(19) United States
(12) Patent Application Publication
(10) Pub. No.: US 2017/0101714 A1
(43) Pub. Date: Apr. 13, 2017

(54) Securing Base, Vapor Deposition Apparatus and Method of Measuring Deformation of To-Be-Treated Substrate

(71) Applicant: BOE TECHNOLOGY GROUP CO., LTD., Beijing (CN)

(72) Inventor: Lei HUANG, Beijing (CN)

(21) Appl. No.: 15/194,976

(22) Filed: Jun. 28, 2016

(30) Foreign Application Priority Data
Oct. 10, 2015 (CN) 201510654561.8

(51) Int. Cl. C23C 16/52

(52) U.S. Cl. CPC C23C 16/52

(57) ABSTRACT

The invention discloses a securing base, a vapor deposition apparatus and a method of measuring deformation of a to-be-treated substrate. The securing base is used for securing a to-be-treated substrate during the vapor deposition process thereof, wherein, at least one grooved channel is disposed at a side of the securing base that faces the to-be-treated substrate, and the grooved channel is provided with at least one deformation measurement unit therein for measuring deformation of an area on the to-be-treated substrate corresponding to the deformation measurement unit during the vapor deposition process. Deformation of the to-be-treated substrate can be measured without interfering the vapor deposition process by providing a grooved channel at a side of the securing base that faces the to-be-treated substrate and providing a corresponding deformation measurement unit within the grooved channel

### CROSS-REFERENCE TO RELATED APPLICATION

This application claims the priority of Chinese Patent Application No. 201510654561.8 filed on Oct. 10, 2015 in the Chinese Intellectual Property Office, the disclosure of which is incorporated herein in its entirety by reference.

### FIELD OF THE INVENTION

The present invention relates to the field of display technology, and more particularly, to a securing base, a vapor deposition apparatus and a method of measuring deformation of a to-be-treated substrate.

### BACKGROUND OF THE INVENTION

In the field of Organic Light-Emitting Diode (OLED) display product manufacture, producing OLED products by vapor deposition is a relatively mature method.

When OLED display products are produced by vapor deposition, some double sided adhesive tape is required to be disposed on a peripheral area of the to-be-treated substrate to secure the to-be-treated substrate below the securing base. Then a corresponding metal mask is disposed at a side of the to-be-treated substrate that is away from the securing base. Finally, the securing base, the to-be-treated substrate and the metal mask are collectively moved to the position above the vapor deposition tank, so as to form a corresponding film by vapor deposition at the side of the to-be-treated substrate that is away from the securing base.

However, because the to-be-treated substrate is merely adhered and secured to the securing base at the peripheral area, there is no acting force between its central area and the securing base. During the vapor deposition process, influenced by its own gravity, the to-be-treated substrate will generate corresponding deformation at the central area. Meanwhile, as the vapor deposition process moves on, a surface temperature of the to-be-treated substrate will change accordingly, which will also cause certain deformation of the to-be-treated substrate. When deformation occurs on the to-be-treated substrate, the deposited pattern may deviate from a predetermined position and thereby lead to defective final products. More importantly, when the deformation of the to-be-treated substrate becomes too great, it will produce debris in the to-be-treated substrate.

Currently, there is not any method that can effectively reduce deformation of the to-be-treated substrate during the vapor deposition process in the art for the following reasons: an operator cannot get the real-time deformation data of the to-be-treated substrate during the vapor deposition process because the whole environment of vapor deposition technique is enclosed, thus research cannot be conducted due to lack of corresponding supporting data. Therefore, how to measure the deformation of the to-be-treated substrate in real time during the vapor deposition process becomes an urgent technical problem to be solved in the art.

### SUMMARY OF THE INVENTION

An object of the invention is to provide a securing base, a vapor deposition apparatus and a method of measuring deformation of a to-be-treated substrate that can effectively measure deformation of a to-be-treated substrate during the vapor deposition process.

To this end, according to one aspect of the invention, there is provided a securing base for securing the to-be-treated substrate during the vapor deposition process thereof, wherein, at least one grooved channel is disposed at a side of the securing base that faces the to-be-treated substrate, and the grooved channel is provided with at least one deformation measurement unit therein for measuring deformation of an area on the to-be-treated substrate corresponding to the deformation measurement unit during the vapor deposition process.

The grooved channel may also be provided with a motion unit that is connected with the deformation measurement unit to drive the deformation measurement unit to move within the grooved channel.

The motion unit may comprise:
a guide rail disposed within the grooved channel; and
a driving unit disposed on the guide rail and connected with the deformation measurement unit to drive the deformation measurement unit to move along the guide rail.

The securing base may further comprise a position acquisition unit for acquiring positional information of the deformation measurement unit during movement.

The grooved channel may comprise at least one first sub-groove extending along a first direction and at least one second sub-groove extending along a second direction; and
any one of the first sub-groove is communicated with at least one of the second sub-grooves, and any one of the second sub-groove is communicated with at least one of the first sub-grooves.

When the securing base comprises a plurality of grooved channels, all of the grooved channels are distributed uniformly on the securing base.

When the securing base is provided with a plurality of deformation measurement units thereon, all of the deformation measurement units are distributed uniformly on the securing base.

The securing base may comprise an alarm unit that is connected with the deformation measurement unit, and the alarm unit alarms when deformation of a corresponding position on the to-be-treated substrate measured by the deformation measurement unit exceeds a preset threshold.

The deformation measurement unit may comprise:
a mechanical sensor provided with a probe thereupon for acquiring a contact force between the probe and the to-be-treated substrate when the probe contacts the to-be-treated substrate; and
a calculation unit for calculating deformation of a position on the to-be-treated substrate that contacts the probe based on the contact force.

When there is a plurality of deformation measurement units, all of the mechanical sensors correspond to one calculation unit.

According to another aspect of the invention, there is provided a vapor deposition apparatus comprising the securing base.

According to yet another aspect of the invention, there is provided a method of measuring deformation of a to-be-treated substrate by a securing base, the securing base is the above said securing base and comprises a position acquisition unit, the deformation measurement unit comprises a calculation unit and a mechanical sensor with a probe, the method comprises the following steps:
the position acquisition unit acquires positional information of the deformation measurement unit and sends the positional information to an exterior device to display;
the mechanical sensor measures a contact force between the probe and the to-be-treated substrate, and sends related data of the contact force to the calculation unit;
the calculation unit queries a deformation value corresponding to the contact force based on a pre-stored relationship mapping table, and sends the deformation value to an exterior device to display; and
an operator binds the positional information with the deformation value, so as to determine deformation of the to-be-treated substrate at the position.

The grooved channel may be provided with a motion unit therein that is connected with the deformation measurement unit to drive the deformation measurement unit to move within the grooved channel, so that one of the deformation measurement units can measure deformation at multiple positions.

The securing base may be provided with a plurality of uniformly distributed deformation measurement units thereon so as to measure deformation at multiple positions at the same time.

In the securing base, the vapor deposition apparatus and the method of measuring deformation of a to-be-treated substrate according to the present invention, deformation of the to-be-treated substrate can be measured without interfering the vapor deposition process by providing a grooved channel at a side of the securing base that faces the to-be-treated substrate and providing a corresponding deformation measurement unit within the grooved channel.

### BRIEF DESCRIPTION OF THE DRAWINGS

FIG. 1 is a structural schematic view illustrating a securing base according to the exemplary embodiment of the invention;

FIG. 2 is a sectional view of the securing base of FIG. 1 secured with a to-be-treated substrate; and

FIG. 3 is a schematic view illustrating a securing base with a plurality of grooved channels according to the exemplary embodiment of the invention.

### DETAILED DESCRIPTION OF THE EMBODIMENTS

Hereinafter, specific embodiments of the present invention will be described in detail with reference to the accompanying drawings. It should be understood that the specific embodiments as set forth herein are merely for the purpose of illustration and explanation of the disclosure and should not be constructed as a limitation thereof.

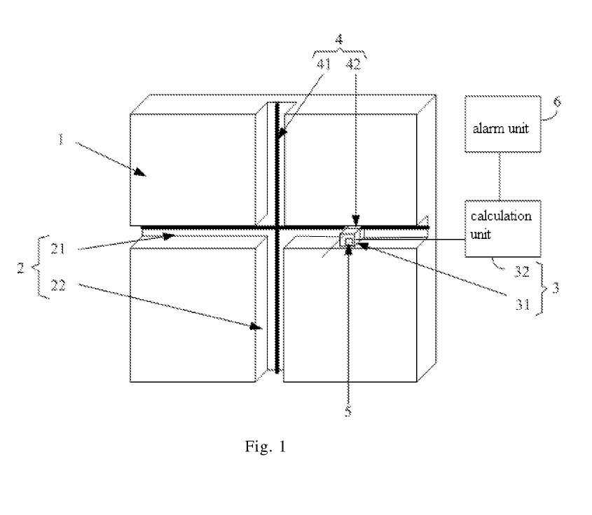

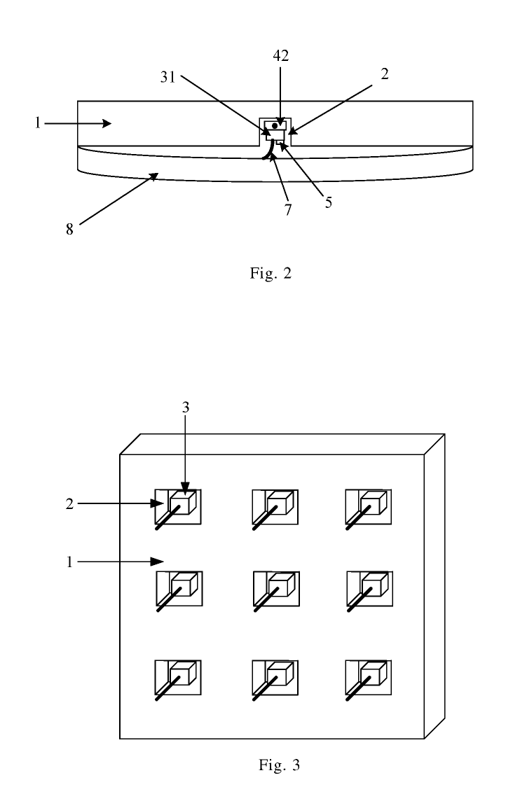

According to one aspect of the invention, there is provided a securing base. FIG. 1 is a structural schematic view illustrating a securing base according to the exemplary embodiment of the invention, and FIG. 2 is a sectional view of the securing base of FIG. 1 secured with a to-be-treated substrate. As shown in FIGS. 1 and 2, the securing base 1 is used for securing a to-be-treated substrate 8 during the vapor deposition process thereof, wherein, at least one grooved channel 2 is disposed at a side of the securing base 1 that faces the to-be-treated substrate 8, the grooved channel 2 is provided with at least one deformation measurement unit 3 therein for measuring deformation of an area on the to-be-treated substrate 8 corresponding to the deformation measurement unit 3 during the vapor deposition process.

It should be noted that the to-be-treated substrate 8 of the embodiment may be a glass substrate.

In the exemplary embodiment of the invention, deformation of the to-be-treated substrate 8 may be measured without interfering the vapor deposition process by providing a grooved channel 2 at a side of the securing base 1 that faces the to-be-treated substrate 8 and providing a corresponding deformation measurement unit 3 within the grooved channel 2.

Alternatively, in the embodiment, the deformation measurement unit 3 may comprise a mechanical sensor 31 and a calculation unit 32. The mechanical sensor 31 provided with a probe 7 thereupon is used for acquiring a contact force between the probe 7 and the to-be-treated substrate 8 when the probe 7 contacts the to-be-treated substrate 8; and the calculation unit 31 is used for calculating deformation of a position on the to-be-treated substrate 8 that contacts the probe 7 based on the contact force.

When measuring deformation of a certain position on the to-be-treated substrate 8 by the deformation measurement unit 3, it only needs to move the deformation measurement unit 3 to a position corresponding to the position to be measured. At this time, the to-be-treated substrate 8 will cause certain deformation of the probe 7 on the mechanical sensor 31, i.e., there is a contact force between the probe 7 and the to-be-treated substrate 8, the specific value of which can be obtained by the mechanical sensor 31 through a corresponding operation; then, related data of the contact force is sent from the mechanical sensor 31 to the calculation unit 32, and the calculation unit 32 queries a deformation value corresponding to the contact force based on a pre-stored relationship mapping table, the resulting deformation value is a deformation value of the to-be-measured position on the to-be-treated substrate 8.

It should be noted that the relationship mapping table stores therein various contact forces and deformation values of to-be-measured positions corresponding to each contact force. Data in the relationship mapping table may be obtained through tests in advance, the specific process of which will not be described in detail here.

In addition, the mechanical sensor 31 is a device of high measurement accuracy that is totally capable of millimeter deformation measurement. Therefore, in the embodiment, obtaining the deformation with the mechanical sensor 31 and the calculation unit 32 is one of the preferable embodiments. In the embodiment, the deformation measurement unit 3 may also be other sensors that can measure a distance or length, so as to measure a space between a certain position on the to-be-treated substrate 8 and a lower surface of the securing base 1, and further obtain deformation of the corresponding position on the to-be-treated substrate 8, which is not illustrated one by one herein.

Alternatively, the securing base 1 further comprises an alarm unit 6 that is connected with the deformation measurement unit 3 and used for alarming when deformation of a corresponding position on the to-be-treated substrate 8 measured by the deformation measurement unit 3 exceeds a preset threshold (which can be set correspondingly according to actual requirements). In the embodiment, by providing the alarm unit 6, it can effectively reduce a risk of the to-be-treated substrate producing shreds.

In the embodiment, more than one deformation measurement unit 3 may be provided on one securing base 1, so that deformation of different positions on the to-be-treated substrate 8 can be measured at the same time. It should be noted that when more than one deformation measurement unit 3 is provided, all of the mechanical sensors 31 may be connected to the same calculation unit 32 that processes data sent from all of the mechanical sensors 31, thereby effectively reducing cost of the apparatus.

It should be further noted that, in the embodiment, data transmission between the mechanical sensor 31 and the calculation unit 32 may be realized in a manner of wire or wireless communication.

Alternatively, the grooved channel 2 may be provided with a motion unit 4 that is connected with the deformation measurement unit 3 to drive the deformation measurement unit 3 to move within the grooved channel 2. Further, the motion unit 4 comprises a guide rail 41 disposed within the grooved channel 2 and a driving unit 42 disposed on the guide rail 41 and connected with the deformation measurement unit 3 to drive the deformation measurement unit 3 to move along the guide rail 41. In the embodiment, by providing the motion unit 4, the deformation measurement unit 3 is movable within the grooved channel 2 so that single deformation measurement unit 3 can measure deformation at multiple positions on the to-be-treated substrate 8. In the embodiment, the driving unit 42 may be a driving motor.

To cooperate with measurement of deformation at multiple positions on the to-be-treated substrate 8 by the deformation measurement unit 3, the securing base 1 according to the exemplary embodiment of the invention further comprises a position acquisition unit 5 that is connected with the deformation measurement unit 3 to acquire a positional information of the deformation measurement unit 3 during movement, and send the acquired positional information, in a manner of wireless communication, to an exterior device to display. Based on the real-time positional information acquired by the position acquisition unit 5 and the real-time deformation data measured by the deformation measurement unit 3, an operator binds the two kinds of data to mark deformation of a certain position on the to-be-treated substrate 8. Obviously, in the embodiment, deformation of each position on the whole to-be-treated substrate 8 may be measured by moving the deformation measurement unit 3 so that collection of deformation of each position on the to-be-treated substrate 8 is completed.

It should be noted that the position acquisition unit 5 of the embodiment may be a position sensor, the working process of which obtaining positional information will not be described in detail here.

Alternatively, each grooved channel 2 on the securing base 1 may comprise at least one first sub-groove 21 extending along a first direction and at least one second sub-groove 22 extending along a second direction, wherein any one of the first sub-groove 21 is communicated with at least one of the second sub-grooves 22, and any one of the second sub-groove 22 is communicated with at least one of the first sub-grooves 21. Then, any two positions within the grooved channel 2 are communicated, so that the deformation measurement unit 3 may be free to move within the corresponding grooved channel 2. Therefore, each grooved channel 2 only needs to be provided with one deformation measurement unit 3, which effectively reduces the number of deformation measurement units 3 on the securing base 1, thereby effectively reducing cost of the apparatus.

It should be noted that although the securing base 1 of FIG. 1 comprises a grooved channel 2 including one first sub-groove 21 extending along a first direction and one second sub-groove 22 extending along a second direction, such arrangement is illustrative and does not limit the technical solution of the invention.

FIG. 3 is a schematic view illustrating a securing base with a plurality of grooved channels according to the exemplary embodiment of the invention. As shown in FIG. 3, the securing base 1 is provided with a plurality of grooved channels 2; and correspondingly, the securing base 1 is provided with a plurality of deformation measurement units 3 thereon. Preferably, all of the deformation measurement units 3 are distributed uniformly on the securing base 1 so that an operator is still able to obtain deformation of each position on the whole to-be-treated substrate 8 as comprehensive as possible even without a motion unit 4 in the grooved channel 2.

It should be noted that the invention does not limit the shape and number of the grooved channels 2 on the securing base 1, or the number of deformation measurement units 3 in each grooved channel 2. Those skilled in the art shall understand that the shape and number of the grooved channels 2 and the number of deformation measurement units 3 are adjustable according to actual requirements.

According to another aspect of the invention, there is provided a vapor deposition apparatus comprising the securing base. Details of the securing base may be referred to the above description and are not repeated here.

According to yet another aspect of the invention, there is provided a method of measuring deformation of the to-be-treated substrate 8 with the securing base 1. As discussed above, the securing base 1 comprises a position acquisition unit 5; the deformation measurement unit 3 comprises a calculation unit 32 and a mechanical sensor 31 with a probe 7. The method comprises the following steps: the position acquisition unit 5 obtains positional information of the deformation measurement unit 3 and sends the positional information to an exterior device to display; the mechanical sensor 31 measures a contact force between the probe 7 and the to-be-treated substrate 8, and sends related data of the contact force to the calculation unit 32; the calculation unit 32 queries a deformation value corresponding to the contact force based on a pre-stored relationship mapping table, and sends the deformation value to an exterior device to display; and an operator binds the positional information with the deformation value to determine deformation of the to-be-treated substrate 8 at the position. Thus, the method of measuring deformation of the to-be-treated substrate 8 with the securing base 1 according to the exemplary embodiment of the invention may monitor deformation of the to-be-treated substrate 8 in real time without interfering the vapor deposition process.

Alternatively, the grooved channel 2 may be provided with a motion unit 4 therein that is connected with the deformation measurement unit 3 to drive the deformation measurement unit 3 to move within the grooved channel 2, so that one of the deformation measurement units 3 can measure deformation at multiple positions. Thus, the number of deformation measurement units 3 on the securing base 1 is effectively reduced, thereby effectively reducing cost of the apparatus.

Alternatively, the securing base 1 may be provided with a plurality of uniformly distributed deformation measurement units 3 thereon so as to measure deformation at multiple positions at the same time. Thus, an operator is still able to obtain deformation of each position on the whole to-be-treated substrate 8 as comprehensive as possible without a motion unit 4 in the grooved channel 2.

It should be understood that the above embodiments are merely exemplary embodiments for the purpose of illustrating the principle of the invention, and the invention is not limited thereto. Various modifications and improvements can be made by a person having ordinary skill in the art without departing from the spirit and essence of the disclosure. Accordingly, all of the modifications and improvements also fall into the protection scope of the invention.

What is claimed is:

1. A securing base for securing a to-be-treated substrate during the vapor deposition process thereof,
wherein at least one grooved channel is disposed at a side of the securing base that faces the to-be-treated substrate, the grooved channel is provided with at least one deformation measurement unit therein for measuring deformation of an area on the to-be-treated substrate corresponding to the deformation measurement unit during the vapor deposition process.

2. The securing base according to claim 1,
wherein the grooved channel is provided with a motion unit that is connected with the deformation measurement unit to drive the deformation measurement unit to move within the grooved channel

3. The securing base according to claim 2,
wherein the motion unit comprises:
a guide rail disposed within the grooved channel; and
a driving unit disposed on the guide rail and connected with the deformation measurement unit to drive the deformation measurement unit to move along the guide rail.

4. The securing base according to claim 2, further comprising a position acquisition unit for acquiring positional information of the deformation measurement unit during movement.

5. The securing base according to claim 1,
wherein the grooved channel comprises at least one first sub-groove extending along a first direction and at least one second sub-groove extending along a second direction; and
any one of the first sub-groove is communicated with at least one of the second sub-grooves, and any one of the second sub-groove is communicated with at least one of the first sub-grooves.

6. The securing base according to claim 1,
wherein when the securing base comprises a plurality of grooved channels, all of the grooved channels are distributed uniformly on the securing base.

7. The securing base according to claim 1,
wherein when the securing base is provided with a plurality of deformation measurement units thereon, all of the deformation measurement units are distributed uniformly on the securing base.

8. The securing base according to claim 1, further comprising an alarm unit,
the alarm unit is connected with the deformation measurement unit; and
the alarm unit alarms when deformation of a corresponding position on the to-be-treated substrate measured by the deformation measurement unit exceeds a preset threshold.

9. The securing base according to claim 1,
wherein the deformation measurement unit comprises:
a mechanical sensor provided with a probe thereupon for acquiring a contact force between the probe and the to-be-treated substrate when the probe contacts the to-be-treated substrate; and
a calculation unit for calculating deformation of a position on the to-be-treated substrate that contacts the probe based on the contact force.

10. The securing base according to claim 9,
wherein when there is a plurality of deformation measurement units, all of the mechanical sensors correspond to one calculation unit.

11. A vapor deposition apparatus comprising the securing base according to claim 1.

12. A method of measuring deformation of a to-be-treated substrate by a securing base, the securing base being the securing base according to claim 1 and comprising a position acquisition unit, the deformation measurement unit comprising a calculation unit and a mechanical sensor with a probe, the method comprising the following steps:
the position acquisition unit acquiring positional information of the deformation measurement unit and sending the positional information to an exterior device to display;
the mechanical sensor measuring a contact force between the probe and the to-be-treated substrate, and sending related data of the contact force to the calculation unit;
the calculation unit querying a deformation value corresponding to the contact force based on a pre-stored relationship mapping table, and sending the deformation value to an exterior device to display; and
an operator binding the positional information with the deformation value, so as to determine deformation of the to-be-treated substrate at the position.

13. The method according to claim 12,
wherein the grooved channel is provided with a motion unit therein that is connected with the deformation measurement unit to drive the deformation measurement unit to move within the grooved channel, so that one of the deformation measurement units can measure deformation at multiple positions.

14. The method according to claim 12,
wherein the securing base is provided with a plurality of uniformly distributed deformation measurement units thereon so as to measure deformation at multiple positions at the same time.
